(19) United States
(12) Patent Application Publication
(10) Pub. No.: US 2026/0316148 A1
(43) Pub. Date: Oct. 15, 2026

(54) SYSTEM FOR MANUFACTURING COIL SPRINGS FROM WIRE, PICKUP DEVICE FOR SUCH A SYSTEM, CLAMPING DEVICE FOR SUCH A SYSTEM

(71) Applicant: WAFIOS Aktiengesellschaft, Reutlingen (DE)

(72) Inventors: Stefan Fries, Reutlingen (DE); Sarah Krauß, Eutingen (DE); Lares Speidel, Mössingen (DE); Frank Weiblen, Metzingen (DE); Bernd Walz, Pfullingen (DE)

(73) Assignee: WAFIOS Aktiengesellschaft, Reutlingen (DE)

(21) Appl. No.: 19/646,426

(22) Filed: Apr. 13, 2026

(30) Foreign Application Priority Data
Apr. 14, 2025 (DE) 10 2025 114 583.0

(51) Int. Cl. B21F 35/00; B65G 51/02

(52) U.S. Cl. CPC B21F 35/00; B65G 51/02

(57) ABSTRACT

A system that manufactures coil springs from wire includes a spring coiling machine having a forming device that forms wire fed to it into a coil spring, and a cutting device that cuts off a respective formed coil spring, and a conveyor system that transports cut-off coil springs from the spring coiling machine to a downstream device of the system, the conveyor system having a pickup device having an inlet opening and defines an initial section of a pipeline of the conveyor system and is designed to receive coil springs that are to be transported away from the spring coiling machine in a direction of conveyance of the conveyor system, the pickup device having an interior space which forms the initial section of the pipeline and into which an already formed spring section of a respective coil spring that is still being formed can be introduced through the inlet opening.

### CROSS-REFERENCE TO RELATED APPLICATIONS

This application claims priority to German Patent Application No. 10 2025 114 583.0, filed Apr. 14, 2025, which is incorporated herein by reference in its entirety.

### TECHNICAL FIELD

This disclosure relates to a system for manufacturing coil springs from wire as well as to a pickup device for such a system and a clamping device for such a system.

### BACKGROUND

Coil springs are machine elements that are required in large quantities and different designs in numerous areas of application. Also known as coiled torsion springs, coil springs are usually made from spring wire and are designed as tension or compression springs depending on the load they will be subjected to during use.

Nowadays, coil springs are usually produced by spring coiling using numerically controlled spring coiling machines. A wire (spring wire) is fed to a forming device of the spring coiling machine and, under the control of an NC control program, formed into a coil spring using tools of the forming device, such as winding mandrels and one or more pitch tools. Upon completion of a forming operation, the finished coil spring is separated from the fed wire under the control of the NC control program by a cutting device.

Further processing and/or inspection steps often follow the forming process to obtain a ready-to-use coil spring with the desired mechanical and geometric properties from the coiled coil spring that has been separated from the wire. Spring coiling machines are therefore often integrated into a complex system (manufacturing system) which, in addition to (at least) one spring coiling machine, comprises (at least) one downstream device and a conveyor system for transporting the coil springs from the spring coiling machine to the downstream device. A downstream device can, for example, have a heat treatment unit and/or a control station for checking the geometric properties of the coil spring (e.g., spring length). For coil springs that require ground ends for their connection, a spring end grinding machine can also be incorporated as a downstream device.

Manufacturing systems of the type described above are known, for example, from DE 10 2020 209 068 A1 and DE 10 2021 211 526 A1.

It could therefore be helpful to provide a system for manufacturing coil springs from wire, a pickup device for such a system, and a clamping device for such a system, each of which has special, in particular improved, properties.

### SUMMARY

Some embodiments provide a system that manufactures coil springs from wire, including: a spring coiling machine including a forming device that forms wire supplied thereto into a coil spring, and a cutting device that cuts a respective formed coil spring from a fed wire, and a conveyor system that transports separated coil springs from the spring coiling machine to a downstream device of the system; wherein the conveyor system has a pipeline which has an inlet opening for entry of the coil springs that are to be transported through the pipeline, wherein the conveyor system has a pickup device, which has the inlet opening and defines an initial section of the pipeline, that receives coil springs that are to be transported away from the spring coiling machine in a direction of conveyance of the conveyor system, wherein the pickup device has an interior space which forms the initial section of the pipeline and into which an already formed spring section of a respective coil spring still being formed can be introduced through the inlet opening, and the interior space of the pickup device widens away from the inlet opening to provide free space for the already formed spring section located inside the interior space to move.

Some embodiments provide a pickup device for a system, wherein the pickup device is designed as a single-part or multi-part adapter device for connection to a pipeline section of the conveyor system; and/or at least one section of the pickup device defining the interior space is monolithically formed and/or additively manufactured.

Some embodiments provide a clamping device for a system, wherein a peripheral wall forms a pipeline section that is adapted for fluid-conducting connection of the interior space of a pickup device of the system; and/or a housing of the clamping device is monolithically formed and/or additively manufactured.

### BRIEF DESCRIPTION OF THE DRAWINGS

FIG. 1 is a schematic side view of a system for manufacturing coil springs from wire according to one embodiment.

FIG. 2 is a schematic perspective view of a detail of the system shown in FIG. 1.

FIG. 3 is a schematic perspective view of a pickup device according to another embodiment.

FIG. 4 is a schematic frontal view of the pickup device according to FIG. 3.

FIG. 5 is a schematic sectional view of the pickup device shown in FIGS. 3 and 4.

FIG. 6 is a schematic perspective view of a pickup device according to another embodiment.

FIG. 7 is a schematic frontal view of the pickup device according to FIG. 6.

FIG. 8 is a schematic sectional view of the pickup device shown in FIGS. 6 and 7.

FIG. 9 is a schematic perspective view of a pickup device according to another embodiment.

FIG. 10 is a schematic perspective view of a pickup device according to another embodiment.

FIG. 11 is a schematic sectional view of a clamping device according to another embodiment.

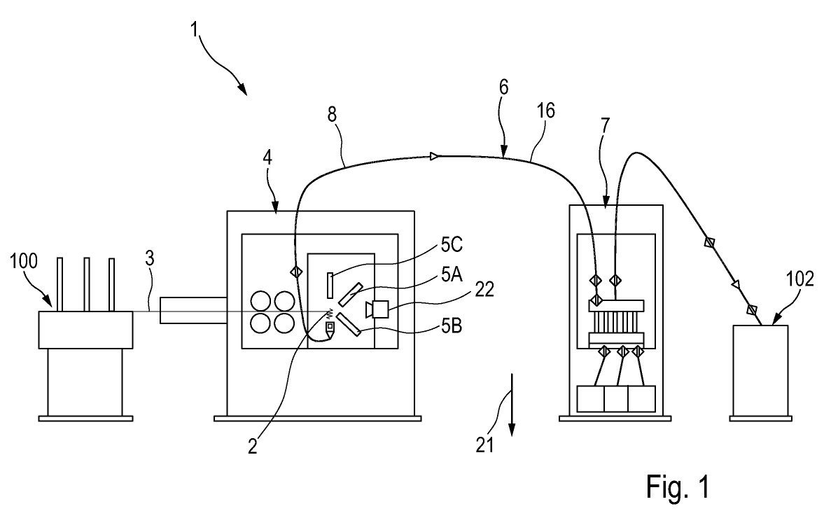

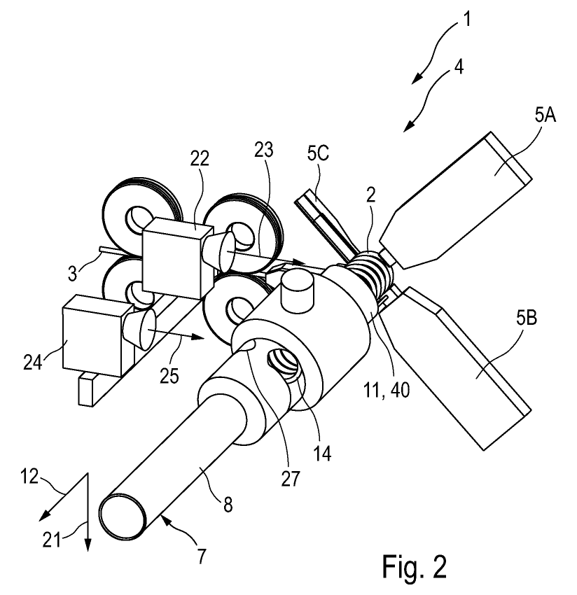

### DETAILED DESCRIPTION

A system is used to manufacture coil springs from wire. The system has a spring coiling machine which has at least one forming device for forming wire fed to the spring coiling machine into a coil spring. The spring coiling machine also has a cutting device which is designed to cut off a finished coil spring from the fed wire. The system has a conveyor system which is designed to transport separated coil springs away from the spring coiling machine to a downstream device of the system. The conveyor system has a pipeline with an inlet opening. A coil spring that has not yet been separated enters the pipeline of the conveyor system through the inlet opening and is then transported through the pipeline. An initial section of the pipeline has the inlet opening. In this respect, the inlet opening can define the foremost end of the initial section of the pipeline in a direction of conveyance of the conveyor system. The conveyor system has a pickup device which is designed to pick up coil springs that are to be transported away from the spring coiling machine in the direction of conveyance. The pickup device has the inlet opening and defines the initial section of the pipe. The pickup device has an interior space which forms the initial section of the pipe. An already formed spring section of a coil spring that is still being formed, e. g. the forming of said coil spring not yet being completed and thus still being in progress, is inserted into the interior space through the inlet opening, particularly to be pushed farther into the interior space forming the initial section of the pipeline as forming progresses.

According to a first aspect of this disclosure, the interior space of the pickup device widens away from the inlet opening. The widened interior space, particularly in the shape of a funnel, provides free space for the already formed spring section located inside the interior space to move. An especially gentle guiding contact of the coil spring still being formed with the pickup device can thus be achieved, particularly to counteract undesirable deformation of the coil spring still being in its forming through contact with the pickup device. This can be advantageous particularly when manufacturing especially delicate coil springs, such as those used in the medical technology sector.

According to a second aspect of this disclosure, the conveyor system of the system has a clamping device which is designed to steady a respective coil spring that is to be transported through the pipeline. In particular, the clamping device can be designed to temporarily clamp and/or secure the relevant coil spring in the pipeline. The clamping device has a pressure chamber that can be filled with a filling fluid, in particular pressurized fluid. The pressure chamber is designed to adjust the inside diameter of the clamping device depending on the internal chamber pressure. In particular, the pressure chamber can be inflated with filling fluid to reduce the inside diameter of the clamping device. Conversely, filling fluid can be drained from the pressure chamber to enlarge the inside diameter. The inside diameter can be set between a minimum value and a maximum value, with possible minimum values being between 80% and 99% of the maximum value, for example. The clamping device has a circumferential wall that defines the adjustable inside diameter. In particular, the circumferential wall has an inside diameter radially on the inside. In particular, the inside of the circumferential wall defines a passage opening. A circular opening cross section of the passage opening in particular can have the inside diameter. In particular, the passage opening forms a pipeline section of the pipeline. The circumferential wall is designed for steadying contact with the relevant coil spring. In particular, the circumferential wall can be elastically deformed by pressurizing the pressure chamber to adapt the inside diameter to an outside diameter of the coil spring that is to be steadied. Placing, in particular clamping, the circumferential wall against a respective coil spring that is currently surrounded by the circumferential wall enables the relevant coil spring to be vibrationally steadied. When the relevant coil spring is in a vibrationally steadied state, an especially precise, particularly optical, measurement of the coil spring can be carried out, particularly in a vibrationally steadied spring section of the coil spring. The steadying contact by the clamping device can be especially advantageous if the system is used to manufacture particularly delicate coil springs such as those used in the medical technology sector.

The two aspects of this disclosure can be implemented together, i.e., in one and the same system for manufacturing coil springs. Alternatively, the two aspects of this disclosure can be implemented independently of each other, meaning that the system for manufacturing coil springs is designed either according to the first aspect of this disclosure or according to the second aspect of this disclosure.

In an embodiment, in particular one that is based at least on the first aspect of this disclosure, the pickup device has a transfer opening which is situated opposite the inlet opening in the direction of conveyance, particularly in alignment. The transfer opening is designed for transferring a respective coil spring from the initial section of the pipeline into a pipeline section of the pipeline downstream of the initial section of the pipeline, in particular directly. In particular, the transfer opening is smaller than the inlet opening, particularly in terms of cross section. The transfer opening can be adapted to an outside diameter of the coil spring in such a way that the coil spring can be guided through the pipeline section along its axial extension in the direction of conveyance and/or that the coil spring automatically aligns itself along the direction of conveyance when it passes through the transfer opening.

In another embodiment, in particular one that is based at least on the first aspect of this disclosure, the interior space widens away from the inlet opening only as far as a widest point of the interior space. The widest point can be located in particular where the interior space has its widest extension perpendicular to the direction of conveyance. Starting from the widest point, the interior space tapers away from the inlet opening, particularly in the direction of conveyance, to the transfer opening, particularly in the shape of a funnel.

Expediently, a lower inner surface section of the pickup device with respect to a vertical direction of the system, which corresponds in particular to a direction of gravity, runs from the inlet opening to the transfer opening parallel to the direction of conveyance, with the lower inner surface section partially defining the interior space.

Expediently, an upper inner surface section of the pickup device partially defining the inner space is situated opposite the lower inner surface section in the vertical direction. The upper inner surface section can be extended longitudinally at an acute angle to the direction of conveyance between the widest point and the transfer opening to form the taper of the inner space away from the widest point toward the transfer opening. Between the widest point and the transfer opening, the upper inner surface section can be used in some areas to allow an axial screw end of the spring section to slide along during ongoing forming to feed this screw end to the transfer opening.

In another embodiment, in particular one that is based at least on the first aspect of this disclosure, the pickup device has two opposing inner flank surfaces, each of which partially defines the interior space. The two inner flank surfaces run parallel to the direction of conveyance.

In another embodiment, in particular one that is based at least on the first aspect of this disclosure, at least one of the inner flank surfaces of the pickup device extends substantially vertically, in particular parallel to the vertical direction of the system. "Substantially" can include angular deviations of 5% to 10%.

In another embodiment, at least one of the inner flank surfaces extends non-vertically, in particular at an inclined angle to a vertical direction of the system. In some embodiments, it may be expedient for both inner flank surfaces to run at an inclined angle to the vertical direction.

In another embodiment, in particular one that is based at least on the first aspect of this disclosure, the already formed spring section of a respective coil spring still being in its forming emerges from the spring coiling machine at an inclined angle, in particular as a function of the spring coil pitch, relative to the vertical direction of the system. An angle between at least one of the inner flank surfaces, in particular one extending non-vertically, and the vertical direction is adapted to the inclined angle in such a way that the spring section rests at least temporarily against the relevant, in particular inclined, inner flank surface during the forming process. The angle and/or the inclined angle can, for example, be a minimum of 30° and/or a maximum of 60°, in particular 40° to 50°.

Expediently, one of the inner flank surfaces can run at an angle to the vertical direction, while the other inner flank surface runs substantially parallel to the vertical direction. This enables a pie-shaped cross section of the interior space to be realized. Alternatively, it may be expedient if both inner flank surfaces run parallel to one another. The inner flank surfaces running parallel to one another can define an elongated hole-like cross-sectional shape of the interior space in certain areas.

In another embodiment, in particular one that is based at least on the first aspect of this disclosure, the system has a measuring camera which is designed to detect a respective coil spring in a capture direction of the measuring camera oriented transverse to the direction of conveyance. The measuring camera is thus able to view the coil spring from the side. The measuring camera is arranged in the direction of conveyance, in particular directly, in front of the inlet opening. The measuring camera can detect the respective coil spring in a detection area that is arranged between the pickup device and the spring coiling machine.

In another embodiment, in particular one that is based at least on the first aspect of this disclosure, the system has a measuring camera, in particular a further measuring camera. The, in particular further, measuring camera is used to detect a respective coil spring along a, in particular further, capture direction of the, in particular further, measuring camera oriented transverse to the direction of conveyance. The, in particular further, measuring camera is arranged in the direction of conveyance, in particular directly, behind the transfer opening of the pickup device or, in particular directly, in front of the transfer opening. The further measuring camera can enable the relevant coil spring to be detected in a further detection area that is arranged at a distance from the inlet opening in the direction of conveyance.

In another embodiment, in particular one that is based at least on the first aspect of this disclosure, the pickup device has a camera window, in particular a recessed camera window. The respective coil spring can be detected through the camera window by the measuring camera, in particular the further measuring camera. The camera window opens the interior space transverse to the direction of conveyance, in particular horizontally. The camera window can be used to open the interior space such that it is permeable to light and/or fluid.

A light inlet opening for a backlight device can be provided opposite the camera window, the relevant coil spring being positioned between the measuring camera and the backlight during measurement.

In another embodiment, in particular one that is based at least on the first aspect of this disclosure, the inlet opening has an opening edge pointing away from the interior space. In particular, the opening edge of the inlet opening can define an extreme end of the pipeline opposite to the direction of conveyance. The opening edge is chamfered or rounded. A chamfer or rounding can therefore be provided on the opening edge. In particular, the opening edge is at least or only partially chamfered or rounded. The chamfer or rounding can make it easier to insert the coil spring into the interior space. For example, a lower area of the opening edge with respect to the vertical direction can be chamfered or rounded, whereas an upper area of the opening edge is substantially without such a chamfer or rounding.

In another embodiment, in particular one that is based at least on the second aspect of this disclosure, the pressure chamber has an annular circumferential design. Alternatively or in addition, the circumferential wall partially delimits the pressure chamber.

The circumferential wall can usefully form an inner tubular portion, in particular one that is elastically deformable, that radially delimits the inside of the pressure chamber.

In another embodiment, in particular one that is based at least on the second aspect of this disclosure, the system has a measuring camera, in particular another measuring camera, which is designed to detect a respective coil spring along a capture direction oriented transverse to the direction of conveyance, in particular another capture direction. The measuring camera, in particular the other measuring camera, is arranged in the direction of conveyance, in particular directly, behind the pressure chamber. In this respect, a spring section of the coil spring that has been vibrationally steadied with the aid of the clamping device can be detected by the measuring camera, in particular the other measuring camera.

In another embodiment, in particular one that is based on the first and/or second aspect of this disclosure, the conveyor system has a nozzle device which is designed to feed a motive fluid into the pipeline and to drive coil springs through the pipeline. The nozzle device opens into the pipeline downstream of the initial section in the direction of conveyance. By the motive fluid, the coil springs can be conveyed through the pipeline in a manner similar to a pneumatic tube system. The nozzle device can be designed to generate a vacuum in the initial section of the pipe. In this respect, the pickup device can be a spring suction device for sucking in springs that are to be transported by the vacuum.

The motive fluid is a gas, in particular air, and more particularly compressed air. Alternatively or in addition, the filling fluid for filling the pressure chamber can be a gas, in particular air, more particularly compressed air.

Expediently, the motive fluid and the filling fluid can come from the same supply source.

In another embodiment, in particular one that is based at least on the second aspect of this disclosure, the clamping device and the nozzle device have a common housing. The clamping device and the nozzle device can therefore be integral with one another.

A pickup device is designed for use in a system, particularly in a system corresponding to at least the first aspect of this disclosure. The pickup device is designed as a one-piece or multi-piece adapter device for connecting to a pipeline section of the conveyor system. Alternatively or in addition, at least one section of the pickup device defining the interior space is monolithic and/or additively manufactured. "Additively manufactured" can be understood to be synonymous with "3D printed."

A clamping device is designed for use in a system, particularly in a system corresponding to at least the second aspect of this disclosure. The circumferential wall of the clamping device forms a pipeline section which is adapted for fluid-conducting connection of the interior space of the pickup device of the system. Alternatively or in addition, a housing of the clamping device is monolithic and/or additively manufactured.

Further advantages and features will be apparent from the following description of exemplary embodiments, which are illustrated with reference to the drawings. Same reference symbols refer to same or similar or functionally identical components.

As will readily be understood, the features mentioned above and those yet to be explained below can be used not only in the combination specified in each case, but also in other combinations or on their own, without departing from the scope of this disclosure.

A system 1 is intended for manufacturing coil springs 2 from wire 3. Such a coil spring 2 to be manufactured can be a helical compression spring or a helical extension spring, each with a cylindrical or non-cylindrical shape. The spring diameter of cylindrical coil springs 2 is constant over the axial length of the coil springs 2. There are also coil springs 2 with spring diameters that vary along their length, for example, conical or barrel-shaped coil springs 2. The overall length of the (unloaded) coil spring 2 can also vary greatly for different applications. The same can apply with regard to the pitch of the coils of coil springs 2.

The system 1 has a spring coiling machine 4. The spring coiling machine 4 can be constructed and operate as described in DE 10 2010 014 385 B4. Other designs are also possible.

The spring coiling machine 4 has a forming device 5A, 5B for forming wire 3 fed to the forming device 5A, 5B into a coil spring 2. The spring coiling machine 4 also has a cutting device 5C which is designed to cut off a respective fully formed coil spring 2 from the fed wire 3.

To produce coil springs 2 from wire 3, the wire 3 can be fed from an "endless" wire supply to the spring coiling machine 4 by a feed device. In this example, this is a computer-numerically controlled spring coiling machine 4. In the spring coiling machine 4, sections of the wire 3 are successively fed to the forming device 5A, 5B by a feed device and formed into coil springs 2 in a forming operation.

The forming device 5A, 5B has in particular forming tools, for example, winding mandrels and optionally one or more pitch tools. Each coil spring 2 is separated from the wire 3 after the forming operation using a cutting device 5C. The separated coil springs 2 are then transported successively, i.e., one by one, through a pipeline 8 of a conveyor system 6 of the system 1 into a spring pickup of a downstream device 7 of the system 1.

The spring coiling machine 4 has, for example, a feed device equipped with feed rollers that feeds successive sections of the wire 3 with a numerically controlled feed rate profile in a horizontal direction into the area of a forming device 5A, 5B. For this purpose, the wire 3 can be drawn in from a wire supply held on a reel 100 of the system 1 and guided through a straightening unit (not shown). In this example, the wire 3 is formed into a coil spring 2 using numerically controlled tools of the forming device 5A, 5B in a spring coiling operation. The forming tools include, for example, two numerically controlled coiling pins arranged with an angular offset of 90° and aligned radially to the desired spring axis and at least one pitch tool for numerically controlling the local pitch of the developing spring 2 at any time. Upon completion of a forming operation, the cutting device 5C can cut a finished coil spring 2 from the fed wire 3 with a linear working movement. The machine axes of the CNC spring coiling machine 4 belonging to the moving components are controlled by a computer numerical control device (not shown).

After being separated from the wire 3, the separated coil springs 2 are automatically conveyed successively to the downstream device 7 in time with the spring coiling machine 4 with the aid of the conveyor system 6. Separated coil springs 2 can thus be taken from the spring coiling machine 4 by the conveyor system 6 and transferred to the downstream device 7. The downstream device 7 can be located several meters away from the spring coiling machine 4, but it may also be closer.

The downstream device 7 comprises, for example, a heat treatment unit 101 for controlled heat treatment of the freshly coiled coil springs 2. Devices for quality control of the heat-treated springs and for sorting and forwarding to at least one further downstream device 102 are integrated, which in this example is downstream of the heat treatment device 101.

The pipeline 8 of the conveyor system 6 has an inlet opening 9 through which the coil springs 2 that are to be transported enter the pipeline 8. The conveyor system 6 has a pickup device 11 that takes coil springs 2 from the spring coiling machine 4, so that a respective coil spring 2 taken from the spring coiling machine 4 can be transported away through the pipeline 8 in a direction of conveyance 12 of the conveyor system 6.

The pickup device 11 has an interior space 13 which forms an initial section 10 of the pipeline 8. The initial section 10 of the pipeline 8 can form a beginning of the pipeline 8, particularly with regard to the direction of conveyance 12. An already formed spring section 14 of a coil spring 2 that is still being formed is inserted into the interior space 13 through the inlet opening 9, i.e., while the forming process is still running.

The interior space 13 of the pickup device 11 widens away from the inlet opening 9. In this example, the interior space 13 widens in the direction of conveyance 12 away from the inlet opening 9. The interior space 13 provides space in which the spring section 14 that is located inside the interior space 13 — and that has already been formed but not yet cut off, for example — can move freely.

The pickup device 11 has a transfer opening 15. A respective coil spring 2 emerges from the initial section 10 of the pipeline 8 through the transfer opening 15 into a pipeline section 16 of the pipeline 8 downstream of the initial section 10 of the pipeline 8. The transfer opening 15 is situated opposite the inlet opening 9 in the direction of conveyance 12. The inlet opening 9 and the transfer opening 15 can be arranged in a common alignment along the direction of conveyance 12. For example, the transfer opening 15 has an opening cross section that is smaller than an opening cross section of the inlet opening 9.

The interior space 13 widens away from the inlet opening 9 only as far as a widest point 18 of the interior space 13. At the widest point 18, the interior space 13 has its largest extent transverse to the direction of conveyance 12. In the direction of conveyance 12, the interior space 13 tapers again from the widest point 18 to the transfer opening 15.

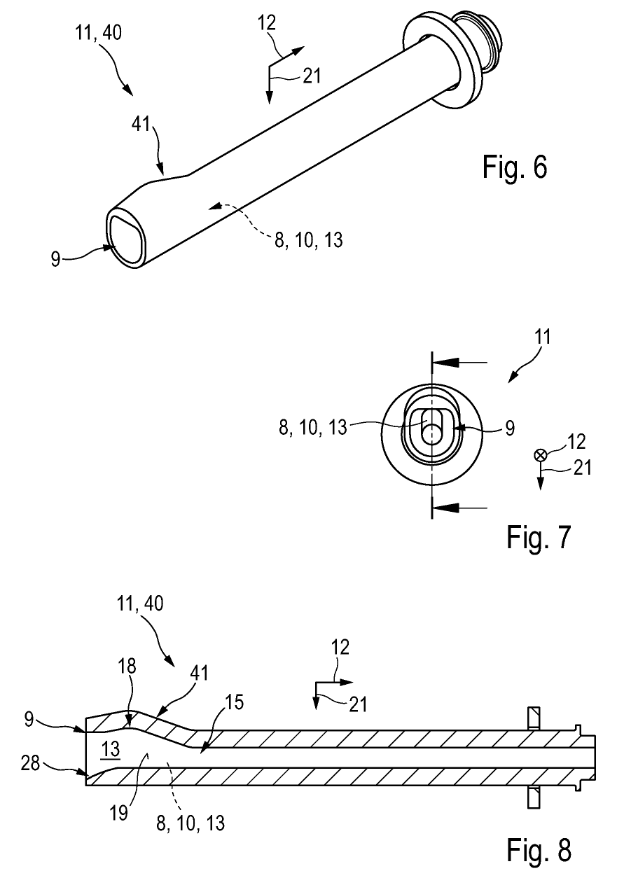

For example, the inlet opening 9 has an opening edge 28 that faces away from the interior space 13. The opening edge 28 can be at least or only partially chamfered or rounded. In the examples shown in FIGS. 6 to 10, only a lower area of the opening edge 28 with respect to the vertical direction 21 is provided with a lead-in chamfer.

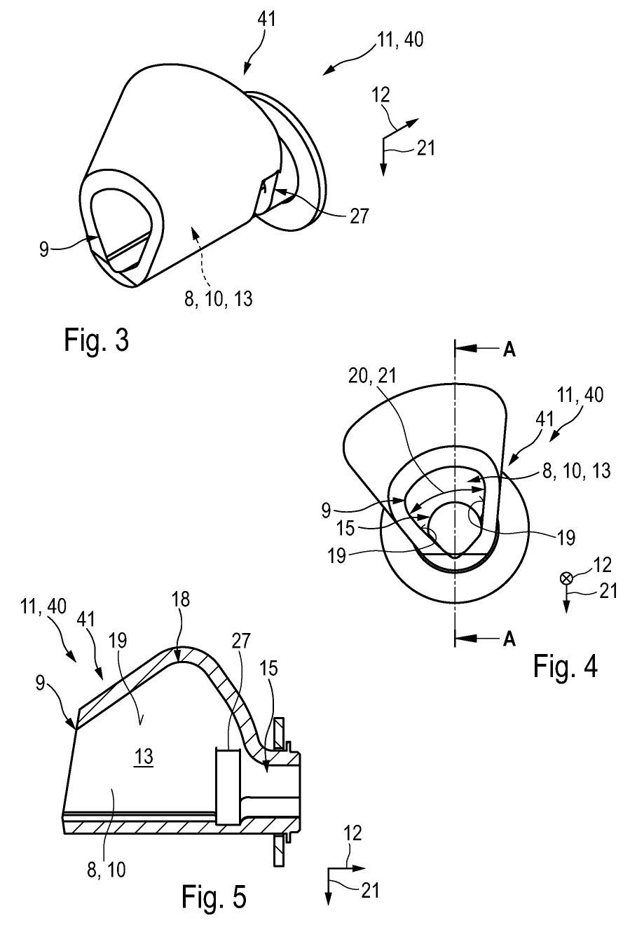

According to the examples according to FIGS. 6 to 10, an inner surface section of the pickup device 11, which delimits the tapering section of the interior space 13, is designed with a taper angle relative to the direction of conveyance 12 which is smaller than a corresponding taper angle in the example according to FIGS. 3 to 5. Such a smaller taper angle can steer an axial end of the spring section 14 especially gently in the direction of the transfer opening 15. This can be especially advantageous if coil springs 2 are manufactured with a relatively long axial spring length. If, on the other hand, coil springs 2 with a comparatively short axial spring length are to be produced, the taper angle can be larger — particularly if the relatively short coil spring 2 in question is produced with a, in particular contacting, last coil winding with a very small pitch, for example, so that as a result of such a very small pitch of the last coil, the coil spring 2 can be aligned independently for transfer through the transfer opening 15 without previously sliding along the tapered inner surface section.

For example, the pickup device 11 has two inner flank surfaces 19 which are arranged opposite one another, in particular transverse to the direction of conveyance 12. The two inner flank surfaces 19 of the pickup device 11 only partially define the interior space 13. The inner flank surfaces 19 run parallel to the direction of conveyance 12.

For example, at least one of the inner flank surfaces 19 runs vertically, i.e., along a vertical direction 21 of the system 1. In the embodiments of FIGS. 6 to 10, both inner flank surfaces 19 run parallel to one another, for example, both vertically or both non-vertically. In contrast, only one of the inner flank surfaces 19 runs substantially vertically in the exemplary embodiment of FIGS. 3 to 5.

For example, the already formed spring section 14 of a coil spring 2 that is still being formed emerges from the spring coiling machine 4 at an inclined angle 20 relative to the vertical direction 21. The inclined angle 20 depends in particular on the pitch of a coil of the coil spring 2 that is currently being formed. If a coil spring 2 is manufactured with a changing spring coil pitch, the inclined angle 20 may change during the forming process. In the embodiment shown in FIGS. 3 to 5, an angle 21 between one of the inner flank surfaces 19 that is extending non-vertically and the vertical direction 21 is adapted to the inclined angle 20. The angle 21 can correspond to the inclined angle 20. In particular, the angle 21 corresponds to a maximum inclined angle 20 occurring during the forming of a coil spring 2 that is currently being manufactured. By adjusting the angle 21 to the inclined angle 20, the spring section 14 can at least temporarily rest against the inner flank surface 19 running at the angle 21 during the forming process.

The spring coiling machine 4 is equipped with a camera-based, optical measuring system for the contactless real-time acquisition of data on the geometry of a spring 2 that is currently being manufactured. The measuring system for measuring a respective coil spring 2 can have a number of measuring cameras 22, 24, 34 of the system 1. The measuring cameras 22, 24, 34 can be embodied as CCD video cameras. By image acquisition, data on the spring geometry of the manufactured coil spring 2 can be determined from the camera images and compared with corresponding data for a desired target geometry in a computer of the control device. This makes it possible to monitor the spring coiling process during the creation of a coil spring 2 and, if necessary, to control the spring coiling process by changing the setting values of tools via feedback from measured values (in-process control). It is also possible to recognize promptly during spring manufacturing whether the manufactured coil spring 2 is a good part (spring geometry within the tolerance range) or a bad part that is to be discarded (spring geometry outside the tolerance range). In this respect, the optical measuring system can function as part of a quality management system.

The measuring camera 22 is designed to detect a respective coil spring 2 in a capture direction 23 of the measuring camera 22 oriented transverse to the direction of conveyance 12. The capture direction 23 can correspond to a viewing direction of the measuring camera 22. The measuring camera 22 is arranged directly in front of the inlet opening 9 in the direction of conveyance 12. The measuring camera 22 is installed in such a way that its field of view can capture a section of the developing coil spring 2 in the vicinity of the tools of the forming device 5A, 5B.

The further measuring camera 24 of the system 1 is designed to detect a respective coil spring 2 along a further capture direction 25 of the measuring camera 24 oriented transverse to the direction of conveyance 12. The further capture direction 25 can correspond to a viewing direction of the further measuring camera 24. The capture direction 23 and the further capture direction 25 can run parallel to one another. The further measuring camera 24 can be used in particular to determine the spring length. Alternatively or in addition, the other measuring camera 34 can be present to determine the spring length.

The further measuring camera 24 can be arranged directly behind the transfer opening 15 of the pickup device 11 in the direction of conveyance 12. Alternatively, the further measuring camera 24 can be arranged directly in front of the transfer opening 15 in the direction of conveyance 12, as in the case in FIGS. 3 to 5, for example.

The pickup device 11 can have a camera window 27 (for example, see FIGS. 3 to 5). The respective coil spring 2 can be detected through the camera window 27 using the further measuring camera 24. The camera window 27 opens the interior space 13 transversely to the direction of conveyance 12. For example, the camera window 27 can open the interior space 13 such that it is permeable to light and/or fluid.

The conveyor system 6 has a clamping device 29. The clamping device 29 is used to steady a respective coil spring 2 that is to be transported through the pipeline 8. The clamping device 29 has a pressure chamber 31 that can be filled with a filling fluid 30. The clamping device 29 has an inside diameter 32 which is variable depending on the filling fluid pressure prevailing in the pressure chamber 31. The pressure chamber 31 can be pressure-filled with the filling fluid 30 to adjust the inside diameter 32 of the clamping device 29 depending on the internal chamber pressure.

The clamping device 29 has a circumferential wall 33, which defines the adjustable inside diameter 32 on its interior. The circumferential wall 33 serves to contact the relevant coil spring 2 on the inside of the circumferential wall 33. The inside diameter 32 can be adjusted so that the inner side of the circumferential wall 33 touches an outer circumference of the relevant coil spring 2.

The pressure chamber 31 has an annular circumferential design, for example. Alternatively or in addition, the circumferential wall 33 partially delimits the pressure chamber 31.

The aforementioned other measuring camera 34 of the system 1 is used in this example to detect a respective coil spring 2 along another capture direction 35 oriented transverse to the direction of conveyance 12. The other measuring camera 34 is arranged directly behind the pressure chamber 31 in the direction of conveyance 12. The measuring camera 34 can therefore be used to measure a section 14 of the coil spring 2 that has been clamped by the clamping device 29 to determine the axial length of the coil spring 2, for example.

The conveyor system 6 has, for example, a nozzle device 36. The nozzle device 36 opens into the pipeline 8 downstream of the initial section 10 in the direction of conveyance 12. The nozzle device 36 is used to feed a motive fluid 37, which drives the coil springs 2 through the pipeline 8. For example, the motive fluid 37 is air 38, in particular compressed air.

The filling fluid 30 for filling the pressure chamber 31 is also air 38 in this example, which in particular comes from the same supply source as the air 38 for the motive fluid 37. In this respect, the filling fluid 30 for filling the pressure chamber 31 can also be compressed air.

The clamping device 29 has a monolithic housing 39. Alternatively or in addition, the housing 39 can — as in this example — be additively manufactured, in particular by a 3D printing process. For example, the housing 39 can be made of a plastic material.

The housing 39 is a common housing of the clamping device 29 and the nozzle device 36.

The circumferential wall 33 of the clamping device 29 forms the aforementioned pipeline section 16 of the pipeline 8. The pipeline section 16 formed by the circumferential wall 33 is adapted to be connected in a fluid-conducting manner to the interior space 13 of the pickup device 11 of the system 1.

At least one section 41 of the pickup device 11 directly surrounding the interior space 13 is monolithic, for example. Alternatively or in addition, at least the section 41 directly surrounding the interior space 13 can be additively manufactured, in particular by a3D printing process. At least the section 41 of the pickup device 11 directly surrounding the interior space 13 can be made of a plastic material.

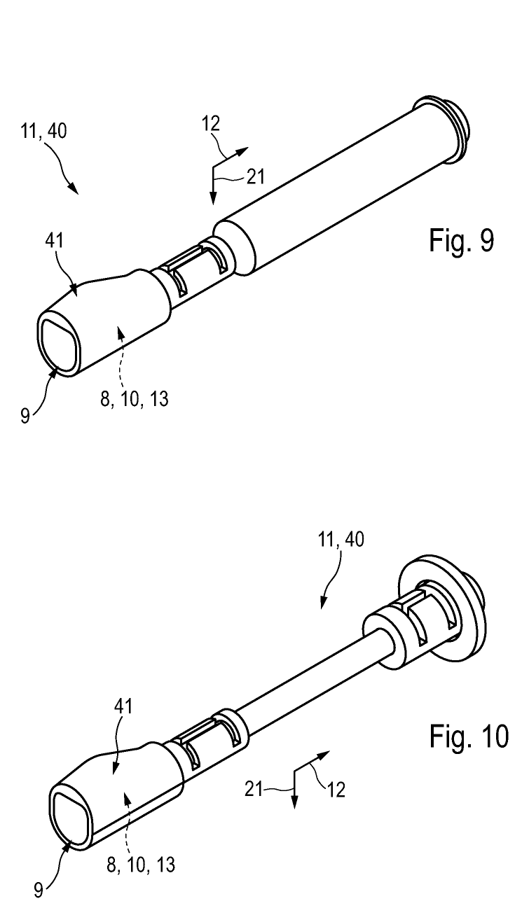

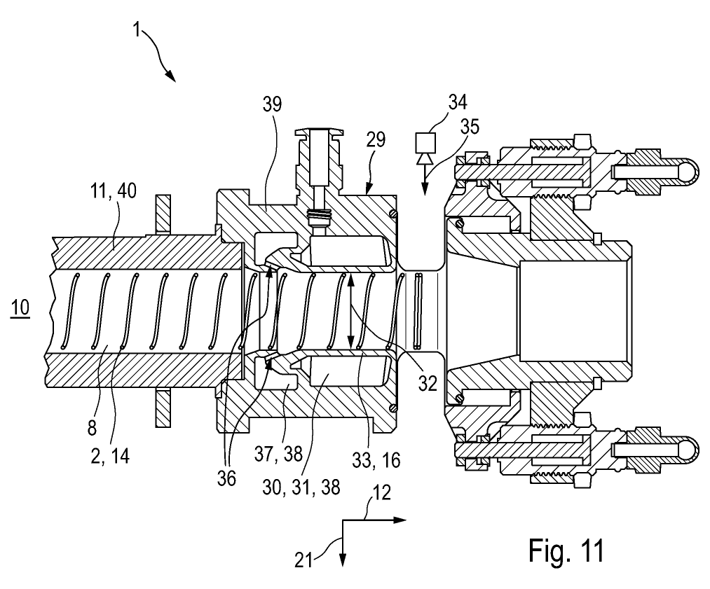

The pickup device 11 can be designed as a single-part or multi-part adapter device 40, the adapter device 40 being designed for connection to the pipeline section 16 of the conveyor system 6. In the examples in FIGS. 3 to 8, the pickup device 11 is designed as a one-piece adapter device 40. In contrast, the pickup device 11 in the examples in FIGS. 9 and 10 is designed as a multi-part adapter device 40. In the example shown in FIG. 9, the adapter device 40 is made up of two parts. In the example shown in FIG. 10, the adapter device 40 is made up of three parts. The multi-part design of the adapter device 40 can make it possible to adapt the adapter device 40 to a type of coil spring 2 currently being manufactured by selecting parts that are joined together to form the adapter device 40, in particular while retaining a part that directly surrounds the interior space 13 and/or is3D-printed.

The pipeline 8 can have a main pipeline section which, for example, connects to the pipeline section 16 and/or the housing 39. The main pipeline section can, for example, consist of a plastic hose made of polytetrafluoroethylene (PTFE) with a very smooth inner pipeline surface, which ensures that the frictional forces between the inner pipeline wall and coil spring 2 remain low over the vast majority of the transport distance. The inside diameter of the main pipeline section is slightly larger than the maximum outside diameter of the coil spring 2, with sufficient radial play remaining for low-friction transportation and with any curved sections of the main pipeline section also being able to be passed through without impairing transport capability.

With the pickup device according to FIGS. 3 to 5, which is set up in particular for the manufacture of short coil springs 2, the illustration in FIG. 4 can also correspond to the installation position. By contrast, in the case of the pickup devices shown in FIGS. 6 to 10, which are set up in particular for the manufacture of long coil springs 2, the installation position can either correspond to the illustration in FIG. 7 or be rotated relative to the illustration in FIG. 7 about the longitudinal axis of the relevant pickup device 11, in particular to adapt to the inclined angle 20.

For example, the two inner flank surfaces 19 of the embodiments shown in FIGS. 6 to 10 can run at an inclined angle to the vertical direction 21 and parallel to one another in the installed position.

What is claimed is:

1. A system that manufactures coil springs from wire, comprising:
a spring coiling machine comprising a forming device that forms wire supplied thereto into a coil spring, and a cutting device that cuts a respective formed coil spring from a fed wire, and
a conveyor system that transports separated coil springs from the spring coiling machine to a downstream device of the system;
wherein the conveyor system has a pipeline which has an inlet opening for entry of the coil springs that are to be transported through the pipeline,
wherein the conveyor system has a pickup device, which has the inlet opening and defines an initial section of the pipeline, that receives coil springs that are to be transported away from the spring coiling machine in a direction of conveyance of the conveyor system,
wherein the pickup device has an interior space which forms the initial section of the pipeline and into which an already formed spring section of a respective coil spring still being formed can be introduced through the inlet opening, and
the interior space of the pickup device widens away from the inlet opening to provide free space for the already formed spring section located inside the interior space to move.

2. The system according to claim 1, wherein
the pickup device has a transfer opening that is situated opposite the inlet opening in the direction of conveyance, or in alignment, for the transfer of a respective coil spring out of the initial section of the pipeline into a pipeline section of the pipeline downstream of the initial section of the pipeline,
wherein the transfer opening is smaller than the inlet opening.

3. The system according to claim 2, wherein the interior space widens away from the inlet opening only as far as a widest point of the interior space to taper again from the widest point to the transfer opening.

4. The system according to claim 1, wherein
the pickup device has two opposing inner flank surfaces which define the interior space,
wherein the two inner flank surfaces run parallel to the direction of conveyance.

5. The system according to claim 4, wherein at least one of the inner flank surfaces runs vertically.

6. The system according to claim 4,
wherein at least one of the inner flank surfaces runs non-vertically or at an inclined angle to a vertical direction of the system; and/or
wherein the two inner flank surfaces run parallel to one another.

7. The system according to claim 4, wherein
the already formed spring section of a respective coil spring still being in its forming emerges from the spring coiling machine at an inclined angle relative to a vertical direction of the system or as a function of a spring coil pitch, and
an angle between at least one of the inner flank surfaces extending non-vertically and the vertical direction is adapted to the inclined angle in such a way that the spring section at least temporarily contacts a relevant inner flank surface during a forming process.

8. The system according to claim 1, wherein
the system has a measuring camera that detects a respective coil spring in a capture direction of the measuring camera, the capture direction being oriented transverse to the direction of conveyance,
wherein the measuring camera is arranged in the direction of conveyance or directly, in front of the inlet opening.

9. The system according to claim 1, wherein
the system has a further measuring camera that detects a respective coil spring along a further capture direction of the further measuring camera oriented transverse to the direction of conveyance,
wherein the further measuring camera is arranged in the direction of conveyance or directly, behind a transfer opening of the pickup device or, directly, in front of the transfer opening.

10. The system according to claim 9, wherein
the pickup device has a camera window through which the respective coil spring can be detected by the further measuring camera,
wherein the camera window opens the interior space transversely to the direction of conveyance such that it is permeable to light and/or fluid.

11. The system according to claim 1, wherein an opening edge of the inlet opening facing away from the interior space is chamfered or rounded at least or only partially.

12. The system according to claim 1, wherein
the conveyor system has a clamping device that steadies a respective coil spring that is to be transported through the pipeline,
wherein the clamping device has a pressure chamber which can be pressure-filled with a filling fluid to adjust an inside diameter of the clamping device as a function of internal chamber pressure,
wherein a circumferential wall of the clamping device designed for steadying contact with a relevant coil spring defines the adjustable inside diameter.

13. The system according to claim 12, wherein
a pressure chamber has an annular circumferential design; and/or
a circumferential wall partially delimits the pressure chamber.

14. The system according to claim 12, wherein
the system has another measuring camera that detects a respective coil spring along another capture direction oriented transverse to the direction of conveyance,
wherein the measuring camera is arranged in the direction of conveyance or directly, behind a pressure chamber.

15. The system according to claim 1, wherein
the conveyor system has a nozzle device opening into the pipeline downstream of the initial section in the direction of conveyance to feed a motive fluid for driving coil springs through the pipeline,
wherein the motive fluid and/or a filling fluid for filling a pressure chamber is air or compressed air from a same supply source.

16. The system according to claim 12, wherein a clamping device and a nozzle device have a common housing.

17. A pickup device for the system according to claim 1, wherein
the pickup device is designed as a single-part or multi-part adapter device for connection to a pipeline section of the conveyor system; and/or
at least one section of the pickup device defining the interior space is monolithically formed and/or additively manufactured.

18. A clamping device for the system according to claim 12, wherein
a peripheral wall forms a pipeline section that is adapted for fluid-conducting connection of the interior space of a pickup device of the system; and/or
a housing of the clamping device is monolithically formed and/or additively manufactured.
